(19) United States
(12) Patent Application Publication
(10) Pub. No.: US 2006/0263633 A1
(43) Pub. Date: Nov. 23, 2006

(54) Organic electroluminescent device

(75) Inventors: Seiji Ichijima, Kanagawa (JP); Tatsuya Igarashi, Kanagawa (JP); Takeshi Murakami, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/410,232

(22) Filed: Apr. 25, 2006

(30) Foreign Application Priority Data
Apr. 27, 2005 (JP) P2005-130062

(51) Int. Cl. H01L 51/54; H05B 33/14

(52) U.S. Cl. 428/690; 428/917; 313/504; 257/E51.044; 546/2; 546/4

(57) ABSTRACT

An organic electroluminescent device comprising: a pair of electrodes; and at least one organic compound layer including a light emitting layer between the pair of electrodes, wherein the at least one organic compound layer contains an organic metal complex having at least one specific ligand.

### BACKGROUND OF THE INVENTION

1. Field of the Invention The present invention relates to an organic electroluminescent device which can emit light by converting electric energy into optical energy.

2. Description of the Related Art

Since an organic electroluminescent device (organic EL device) can emit high-brightness light with a low voltage, the organic EL device has attracted attention as a promising display device. External quantum efficiency is an important characteristic of the organic EL device. The external quantum efficiency is calculated as “external quantum efficiency Φ=the number of photons emitted from a device/the number of electrons injected into the device,” and it can be said that it is more advantageous in view of power consumption as the external quantum efficiency becomes greater.

The external quantum efficiency of an organic EL device is determined as “external quantum efficiency Φ=internal quantum efficiency×light extraction efficiency.” In an organic EL device using fluorescent light emission from an organic compound, since the limit value of the internal quantum efficiency is about 25% and the light extraction efficiency is about 20%, the limit value of the external quantum efficiency is about 5%.

As a method for enhancing the internal quantum efficiency of the organic electroluminescent device to enhance the external quantum efficiency, there has been suggested an organic electroluminescent device using a triplet light emitting material (phosphorescent material) including an iridium complex. For example, there is known a blue-green light emitting device using light emission from a fluorine substituent of a tris-ortho-metalated complex of iridium (III) with 2-phenylpyridine (Ir(ppy)₃) (J. Am. Chem. Soc., 125(24), 7377(2003)). However, improvement in durability and efficiency has been required for the device.

There has been also suggested a device using a triplet light emitting material (phosphorescent material) including a platinum complex (WO 2004/039781 and WO 2004/039914). The device has an external quantum efficiency more enhanced than that of a conventional device (singlet light emitting device) using fluorescent light emission, but improvement in durability and efficiency has been also required for the device.

### SUMMARY OF THE INVENTION

An object of the present invention is to provide an organic electroluminescent device having excellent durability and excellent light emission efficiency.

The above-mentioned object could be accomplished by the following means.

(1) An organic electroluminescent device comprising:

a pair of electrodes; and

at least one organic compound layer including a light emitting layer between the pair of electrodes,
wherein the at least one organic compound layer contains an organic metal complex having at least one ligand represented by Formula (1);

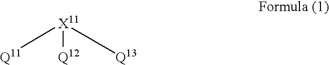

wherein X¹¹ represents an atom or an atom group which is bonded to Q¹¹ to Q¹³; and

Q¹¹ to Q¹³ each independently represents an atom group which is banded to or coordinates with a metal ion.

(2) The organic electroluminescent device as described in (1) above,
wherein X¹¹ in the ligand represented by Formula (1) is an atom group containing an atom bonded to Q¹¹ to Q¹³, or a trivalent atom bonded to Q¹¹ to Q¹³.

(3) The organic electroluminescent device as described in (2) above,

wherein the organic metal complex is an organic metal complex represented by Formula (2) or (3):

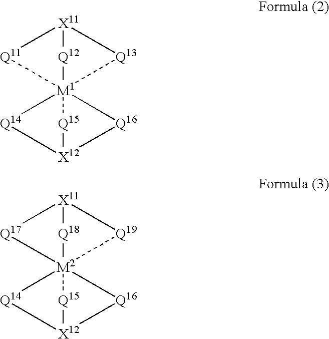

wherein X¹¹ represents an atom group containing an atom-bonded to Q¹¹ to Q¹³ or Q¹¹ to Q¹⁹, or a trivalent atom bonded to Q¹¹ to Q¹³ or Q¹⁷ to Q¹⁹;

X¹² represents an atom group containing an atom bonded to Q¹⁴ to Q¹⁶ or a trivalent atom bonded to Q¹⁴ to Q¹⁶;

Q¹¹ to Q¹⁹ each independently represents an atom group which is bonded to or coordinates with a metal ion M¹ or M²;

M¹ represents an iridium ion; and

M² represents a platinum ion.

(4) The organic electroluminescent device as described in any of (1) to (3) above,

wherein the atom group represented by Q¹¹ to Q¹⁹ in Formula (1), Formula (2) or Formula (3) is an aromatic group or a five-membered or six-membered heterocyclic group containing at least one atom selected from a nitrogen atom, a sulfur atom and an oxygen atom.

(5) The organic electroluminescent device as described in any of (1) to (4) above,

wherein the light emitting layer contains a phosphorescent material.

(6) The organic electroluminescent device as described in any of (1) to (5) above,

wherein when X¹¹ represents an atom group containing an atom bonded to Q¹¹ to Q¹⁹ in Formula (1), Formula (2) or Formula (3), the atom bonded to Q¹¹ to Q¹⁹ is a carbon atom, a nitrogen atom or a phosphorus atom.

### DETAILED DESCRIPTION OF THE INVENTION

The present invention provides an organic electroluminescent device having at least one organic compound layer including a light emitting layer between a pair of electrodes, wherein the at least one organic compound layer contains an organic metal complex (hereinafter, also referred to as “organic metal complex according to the present invention”) having at least one ligand represented by Formula (1).

In the present invention, a hexadentate iridium or platinum complex is particularly desirable as the organic metal complex having at least one ligand represented by Formula (1).

A hexadentate complex having two tridentate ligands with trivalent iridium is a desirable example the iridium complex according to the present invention.

A desirable example of the platinum complex according to the present invention is a hexadentate complex having two tridentate ligands with quadrivalent platinum.

Since a metal in such complexes has a hybrid orbital in the form of d²sp³ (in classical expression) and a bond around the metal has an octahedral structure, the complexes are very stable. Accordingly, it is possible to emit light with excellent durability.

Formula (1) is explained. X¹¹ represents an atom or an atom group which is bonded to Q¹¹ to Q¹³.

When X¹¹ represents an atom, the atom may be a nitrogen atom or a phosphorus atom. The desirable example of the atom is a nitrogen atom. When X¹¹ represents an atom group, X¹¹ is preferably an atom group containing one atom bonded to Q¹¹ to Q¹¹, and is more preferably “≡C—R¹” or “≡P═O”. Here, “≡” indicates bond hands bonded to Q¹¹ to Q¹³. R¹ is not particularly limited, but examples thereof can include an alkyl group (such as a methyl group and a dimethyl group), an alkenyl group (such as a vinyl group and a methylvinyl group), an alkinyl group (such as an ethinyl group), an aryl group (such as a phenyl group and a 1-carbazolephenyl group), an aralkyl group (such as a benzyl group), an alkoxy group (such as a methoxy group), an alkylthio group (such as a methylthio group and an ethylthio group), an aryloxy group (such as a phenoxy group), an arylthio group (such as a phenylthio group), and a five-membered or six-membered heterocyclic group (such as a pyrazolyl group and a triazolyl group) having at least one atom of nitrogen, sulfur, and oxygen atoms. The examples can further include groups (such as a methoxymehtyl group) obtained by combining them. Among them, the alkyl group and the aryl group are more preferable. The groups have preferably a carbon number of 1 to 22 and more preferably a carbon number of 1 to 16.

Q¹¹ to Q³ represent an atom group bonded to or coordinating with a metal ion, and examples thereof can include an aromatic group (of which the carbon number is preferably in the range of 6 to 10 and examples of which can include a phenylene group and a naphthylene group) and a five-membered or six-membered heterocyclic group (such as a pyridyl group, a pyrazolyl group, a 1,2,4-triazolyl group, a thiophenyl group, a furyl group, and a quinolyl group) having at least one atom of nitrogen, sulfur, and oxygen atoms. Among them, the aromatic group, the pyridyl group, and the pyrazolyl group are more preferable.

Formulas (2) and (3) are explained. X¹¹ and Q¹¹ to Q¹³ are the same as those described with reference to Formula (1). X¹² is the same as X¹¹ and Q¹⁴ to Q¹⁶ and Q¹⁷ to Q¹⁹ are the same as Q¹¹ to Q¹³.

Examples of the compounds represented by Formulas (2) and (3) can neutral molecules. That is, a trivalent iridium metal is a desirable example of M¹ in Formula (2). For example, Q¹², Q¹⁴, and Q¹⁶ are preferably atom groups having monovalent anion as formal charge, and Q¹¹, Q¹³, and Q¹⁵ are preferably atom groups not having formal charge.

A quadrivalent platinum metal is a desirable example of M² in Formula (3). For example, Q¹⁴, Q¹⁶, Q¹⁷, and Q¹⁸ are preferably atom groups having monovalent anion as formal charge, and Q¹⁵ and Q¹⁹ are preferably atom groups not having formal charge.

A divalent aromatic group or heterocyclic group is a desirable example of Q¹¹ to Q¹⁹. These are the same as Q¹¹ to Q¹³ described with reference to Formula (1), except for the valence number.

In X¹¹, X¹², and Q¹¹ to Q¹⁹, the aromatic group or the heterocyclic group may be a substituent group. In this case, examples of the substituent group can include an alkyl group (which has preferably a carbon number of 1 to 30, more preferably a carbon number of 1 to 20, and most preferably a carbon number of 1 to 10, and examples of which can include methyl, ethyl, iso-propyl, tert-butyl, n-octyl, n-decyl, n-hexadecyl, cyclopropyl, cyclopentyl, and cyclohexyl), an alkenyl group (which has preferably a carbon number of 2 to 30, more preferably a carbon number of 2 to 20, and most preferably a carbon number of 2 to 10, and examples of which can include vinyl aryl, 2-butenyl, and 3-pentenyl), an alkinyl group (which has preferably a carbon number of 2 to 30, more preferably a carbon number of 2 to 20, and most preferably a carbon number of 2 to 10, and examples of which can include propargyl and 3-pentinyl), an aryl group (which has preferably a carbon number of 6 to 30, more preferably a carbon number of 6 to 20, and most preferably a carbon number of 6 to 12, and examples of which can include phenyl, p-methylphenyl, naphthyl, and anthranil), an amino group (which has preferably a carbon number of 0 to 30, more preferably a carbon number of 0 to 20, and most preferably a carbon number of 0 to 10, and examples of which can include amino, methyl amino, dimethyl amino, diethyl amino, dibenzyl amino, diphenyl amino, and ditolyl amino), an alkoxy group (which has preferably a carbon number of 1 to 30, more preferably a carbon number of 1 to 20, and most preferably a carbon number of 1 to 10, and examples of which can include methoxy, ethoxy, butoxy, and 2-ethylhexyloxy), an aryloxy group (which has preferably a carbon number of 6 to 30, more preferably a carbon number of 6 to 20, and most preferably a carbon number of 6 to 12, and examples of which can include phenyloxy, 1-naphtayloxy, and 2-naphthyloxy), a heterocyclic oxy group (which has preferably a carbon number of 1 to 30, more preferably a carbon number of 1 to 20, and most preferably a carbon number of 1 to 12, and examples of which can include pyridyloxy, pyrazyloxy, pyrimidyloxy, and quinolyloxy), and an acyl group (which has preferably a carbon number of 1 to 30, more-preferably a carbon number of 1 to 20, and most preferably a carbon number of 1 to 12, and examples of which can include acetyl, benzoyl, formyl, and pivaloyl).

Examples of the substituent group described above can include an alkoxycarbonyl group (which has preferably a carbon number of 2 to 30, more preferably a carbon number of 2 to 20, and most preferably a carbon number of 2 to 12, and examples of which can include methoxycarbonyl and ethoxycarbonyl), an aryloxycarbonyl group (which has preferably a carbon number of 7 to 30, more preferably a carbon number of 7 to 20, and most preferably a carbon number of 7 to 12, and examples of which can include phenyloxycarbonyl), an acyloxy group (which has preferably a carbon number of 2 to 30, more preferably a carbon number of 2 to 20, and most preferably a carbon number of 2 to 10, and examples of which can include acetoxy and benzoyloxy), an acyl amino group (which has preferably a carbon number of 2 to 30, more preferably a carbon number of 2 to 20, and most preferably a carbon number of 2 to 10, and examples of which can include acetyl amino and benzoyl amino), an alkoxycarbonyl amino group (which has preferably a carbon number of 2 to 30, more preferably a carbon number of 2 to 20, and most preferably a carbon number of 2 to 12, and examples of which can include methoxycarbonyl amino), an aryloxycarbonyl amino group (which has preferably a carbon number of 7 to 30, more preferably a carbon number of 7 to 20, and most preferably a carbon number of 7 to 12, and examples of which can include phenyloxycarbonyl amino), a sulfonyl amino group (which has preferably a carbon number of 1 to 30, more preferably a carbon number of 1 to 20, and most preferably a carbon number of 1 to 12, and examples of which can include methane sulfonyl amino and benzene sulfonyl amino), a sulfamoyl group (which has preferably a carbon number of 0 to 30, more preferably a carbon number of 0 to 20, and most preferably a carbon number of 0 to 12, and examples of which can include sulfamoyl, methylsulfamoyl, dimethylsulfamoyl, and phenylsulfamoyl), a carbamoyl group (which has preferably a carbon number of 1 to 30, more preferably a carbon number of 1 to 20, and most preferably a carbon number of 1 to 12, and examples of which can include carbamoyl, methylcarbamoyl, diethylcarbamoyl, and phenylcarbamoyl), and an alkylthio group (which has preferably a carbon number of 1 to 30, more preferably a carbon number of 1 to 20, and most preferably a carbon number of 1 to 12, and examples of which can include methylthio and ethylthio)

Examples of the substituent group described above can include an arylthio group (which has preferably a carbon number of 6 to 30, more preferably a carbon number of 6 to 20, and most preferably a carbon number of 6 to 12, and examples of which can include phenylthio), a heterocyclic thio group (which has preferably a carbon number of 1 to 30, more preferably a carbon number of 1 to 20, and most preferably a carbon number of 1 to 12, and examples of which can include pyridylthio, 2-benzimizolylthio, 2-benzoxazolylthio, and 2-benzthiazolylthio), a sulfonyl group (which has preferably a carbon number of 1 to 30, more preferably a carbon number of 1 to 20, and most preferably a carbon number of 1 to 12, and examples of which can include mesyl and tosyl), a sulfinyl group (which has preferably a carbon number of 1 to 30, more preferably a carbon number of 1 to 20, and most preferably a carbon number of 1 to 12, and examples of which can include methane sulfinyl and benzene sulfinyl), an ureido group (which has preferably a carbon number of 1 to 30, more preferably a carbon number of 1 to 20, and most preferably a carbon number of 1 to 12, and examples of which can include ureido, methylureido, and phenylureido), an amide phosphate group (which has preferably a carbon number of 1 to 30, more preferably a carbon number of 1 to 20, and most preferably a carbon number of 1 to 12, and examples of which can include diethyl amide phosphate and phenyl amide phosphate), an hydroxy group, a mercapto group, a halogen atom (examples of which can include a fluorine atom, a chlorine atom, a bromine atom, and an iodine atom), a cyano group, a sulfo group, a carboxyl group, a nitro group, a hydroxamic group, a sulfino group, a hydrazino group, an imino group, a heterocyclic group (which has preferably a carbon number of 1 to 30 and more preferably a carbon number of 1 to 12 and which includes, for example, a nitrogen atom, an oxygen atom, and a sulfur atom as the hetero atom, examples of which can include imidazolyl, pyridyl, quinolyl, furyl, thienyl, piperidyl, morpholino, benzoxazolyl, benzimidazolyl, benzthiazolyl, carbazolyl, and azepinyl), a silyl group (which has preferably a carbon number of 3 to 40, more preferably a carbon number of 3 to 30, and most preferably a carbon number of 3 to 24, and examples of which can include trimethylsilyl and triphenylsilyl), and a silyloxy group (which has preferably a carbon number of 3 to 40, more preferably a carbon number of 3 to 30, and most preferably a carbon number of 3 to 24, and examples of which can include methylsilyloxy and triphenylsilyloxy). These substituent groups may be substituted again.

Compound examples of the organic metal complex according to the present invention will be described below, but the present invention is not limited to the example. In the compound examples, a bond between a metal ion and a ligand indicated by a solid line represents a covalent bond, and a bond between a metal ion and a ligand indicated by a dotted line represents a coordinate bond.

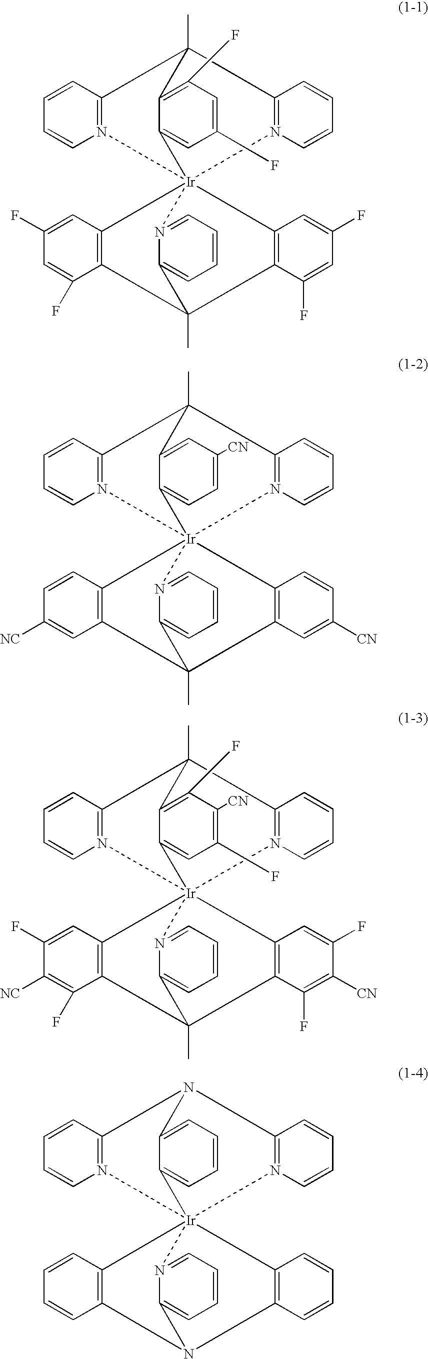

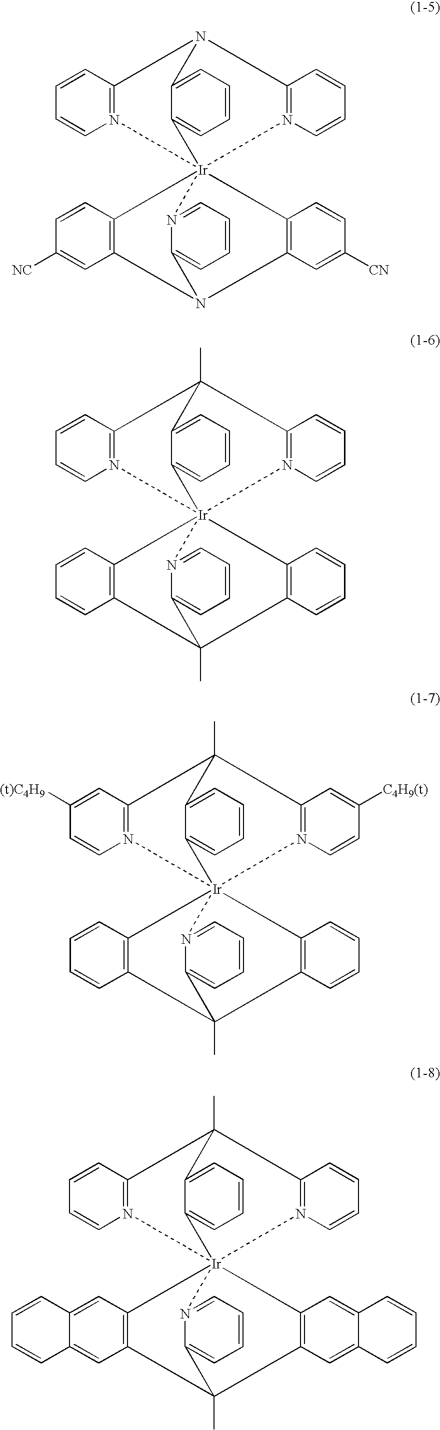

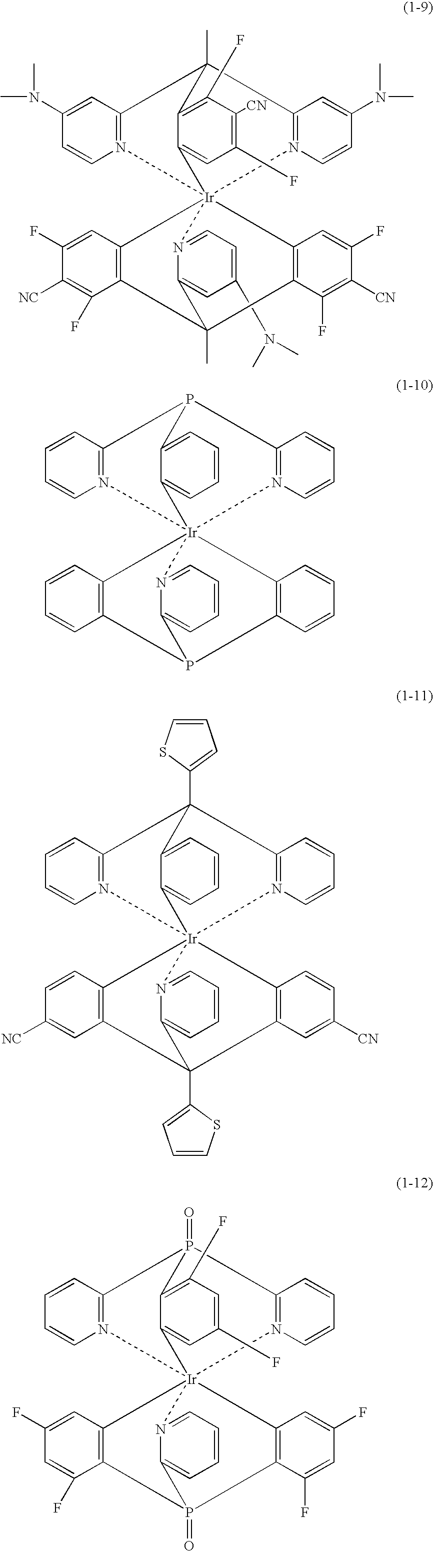

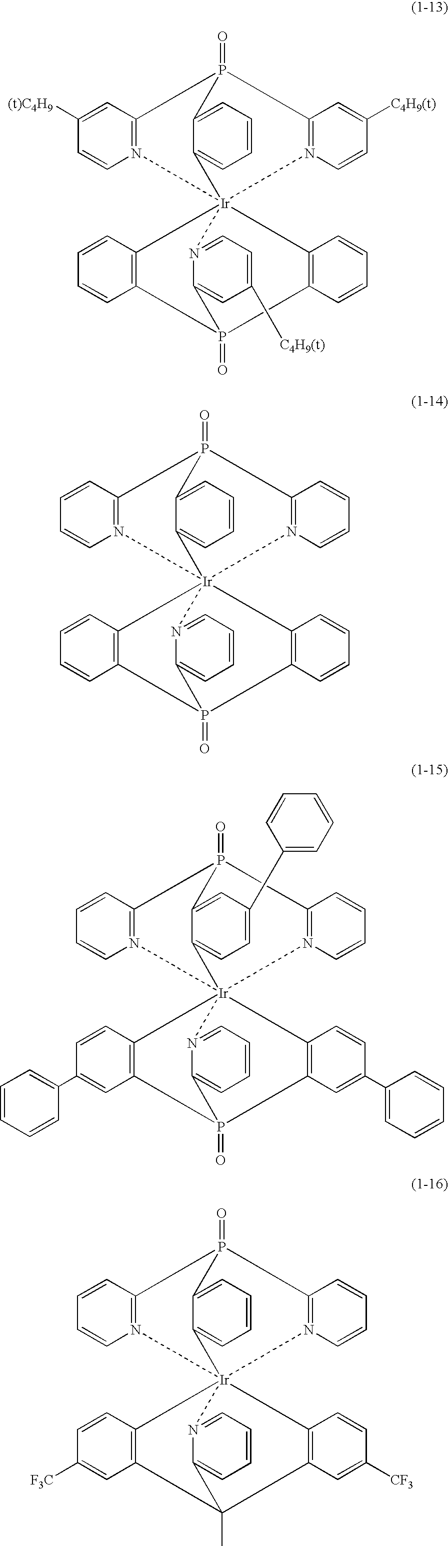

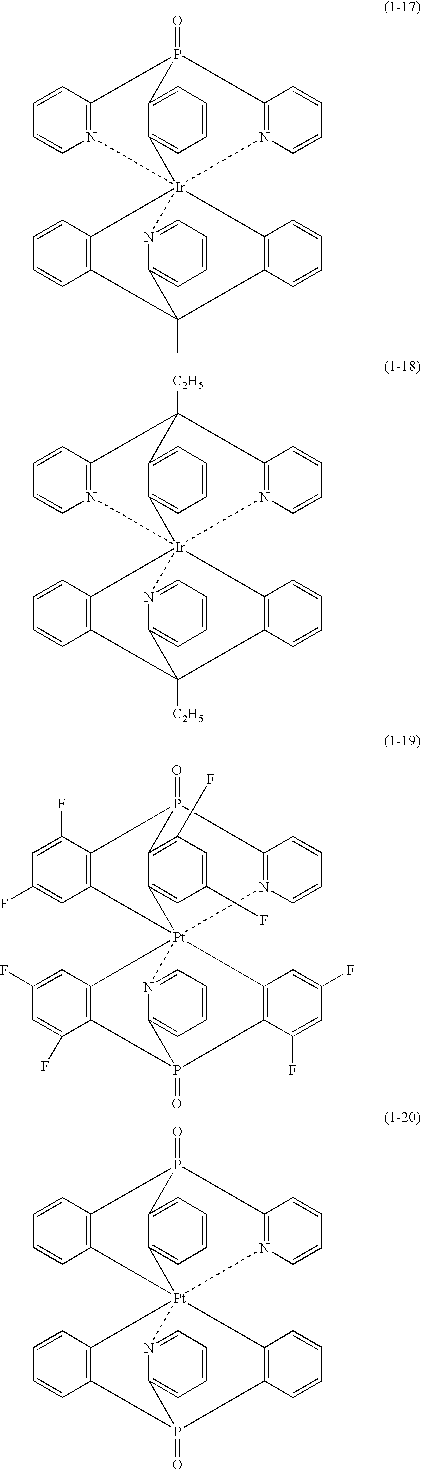

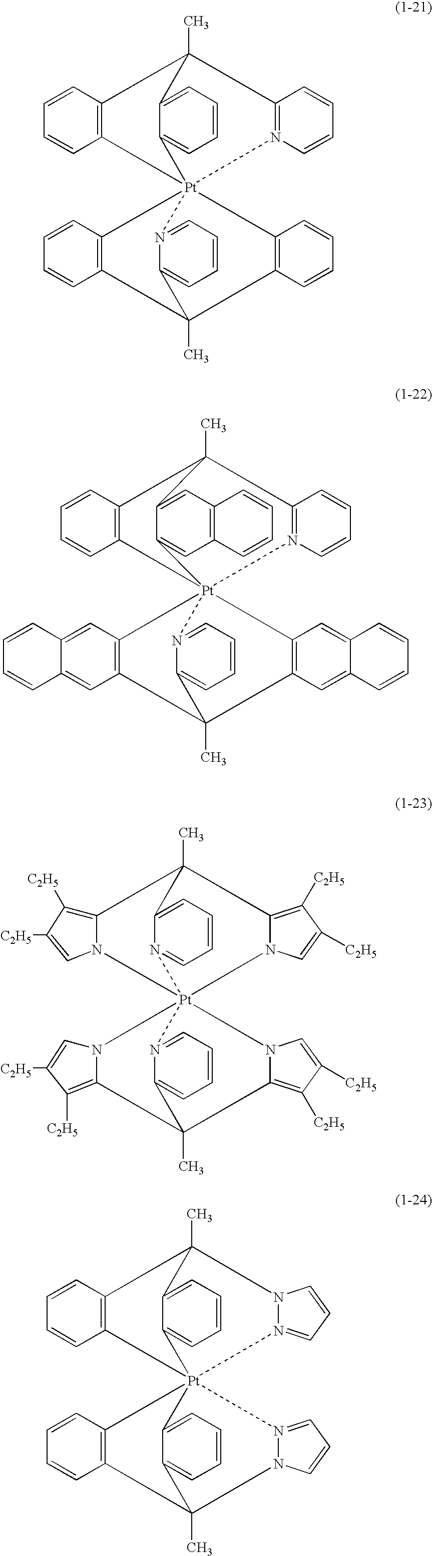

The organic metal complexes according to the present invention can be synthesized by mixing a ligand with a metal source (for example, platinum chloride, palladium chloride, potassium platinum chloride, sodium palladium chloride, platinum bromide, and platinum acetylacetone complex) under existence or non-existence of a solvent (for example, acetonitrile, benzonitrile, acetic acid, ethanol, methoxyethanol, glycerol, water, and a mixture solvent thereof). An additive (for example, trifluoromethane silver sulfide) for activating the reaction may be added thereto, the reaction may be performed under existence of inert gas (such as nitrogen and argon).

The reaction temperature is not particularly limited, but is preferably in the range of −30° C. to 400° C., more preferably in the range of 0° C. to 350° C., and most preferably in the range of 25° C. to 300° C.

The organic metal complex according to the present invention may be a low-molecular compound, or may be an oligomer compound or a polymer compound having a platinum complex in a main chain or a side chain (of which the weight-average molecular weight (in polystyrene equivalent) is preferably in the range of 1,000 to 5,000,000, more preferably in the range of 2,000 to 1,000,000, and still more preferably in the range of 3,000 to 100,000). The organic metal compound according to the present invention is preferably a low-molecular compound.

The organic electroluminescent device according to the present invention has a light emitting layer or a plurality of organic compound layers including the light emitting layer, which is formed between a pair of electrodes of a positive electrode and a negative electrode. The organic compound layer may include a hole injecting layer, a hole transporting layer, an electron injecting layer, an electron transporting layer, and a protective layer, in addition to the light emitting layer. The respective layers may have different functions. A variety of materials may be used to form the respective layers. The organic compound mentioned here includes an organic metal complex.

The organic electroluminescent device according to the present invention has preferably at least three layers of the hole transporting layer, the light emitting layer, and the electron transporting layer. It is preferable that the light emitting layer includes at least two kinds of materials such as a host material and a fluorescent material.

The organic metal complex according to the present invention, specifically, the iridium complex and the platinum complex described above, can be used in the respective layers described above and preferably in the light emitting layer, but the present invention is not limited to it. For example, the organic metal complex may be used as a charge transporting material or a host material used for the light emitting layer.

It is preferable that the platinum complex according to the present invention is used as the charge transporting material or the host material. When the platinum complex is used as the host material, a blue phosphorescent material can be used as an impurity (light emitting material).

The phosphorescent quantum yield of the phosphorescent material is preferably 30% or more, more preferably 50% or more, still more preferably 70%, and most preferably 90% or more.

The phosphorescent quantum yield of the phosphorescent material can be measured by freezing and degassing the phosphorescent material (for examples, a concentration of 1×10⁻³ mol/l) dissolved in an organic solvent (such as toluene, dichloroethane) and then comparing the amount of light emission resulting from irradiation of light at a room temperature with that of a material (such as fluorescein, anthracene, and rhodamine) of which the absolute fluorescent quantum yield is known.

The phosphorescent life time of the phosphorescent material is preferably 10 μs or less, more preferably 5 μs or less, and most preferably 3 μs or less.

The phosphorescent life time of the phosphorescent material can be obtained by freezing and degassing the phosphorescent material (for examples, a concentration of 1×10⁻³ mol/l) dissolved in an organic solvent (such as toluene, dichloroethane) and then measuring the life time of light at the time of irradiation of light at a room temperature.

In the organic electroluminescent device according to the present invention, the external quantum efficiency is preferably 5% or more, more preferably 10% or more, and most preferably 13% or more. As the value of the external quantum efficiency, the maximum value of the external quantum efficiency when the device is driven at 20° C. may be used or the value of the external quantum efficiency when the device is driven in the range of 100 to 300 cd/m² at 20° C. may be used.

In the organic electroluminescent device according to the present invention, the internal quantum efficiency is preferably 30% or more, more preferably 50% or more, and most preferably 70% or more. The internal quantum efficiency is calculated as “internal quantum efficiency=external quantum efficiency/light extraction efficiency.” The light extraction efficiency of a conventional organic EL device is about 20%, but the light extraction efficiency may be set to 20% or more by devising the shape of a substrate, the shape of an electrode, the thickness of an organic compound layer, the thickness of an inorganic layer, the refractive index of an organic layer, the refractive index of an inorganic layer, and the like.

The ionization potential of the host material contained in the light emitting layer according to the present invention is preferably in the range of 5.8 eV to 6.3 eV, more preferably in the range of 5.95 eV to 6.25 eV, and most preferably in the range of 6.0 eV to 6.2 eV.

The electron mobility of the host material contained in the light emitting layer is preferably in the range of 1×10⁻⁶ Vs/cm to 1×10⁻¹ Vs/cm, more preferably in the range of 5×10⁻⁶ Vs/cm to 1×10⁻² Vs/cm, still more preferably in the range of 1×10⁻⁵ Vs/cm to 1×10⁻² Vs/cm, and most preferably in the range of 5×10⁻⁵ Vs/cm to 1×10⁻² Vs/cm.

The hole mobility of the host material contained in the light emitting layer is preferably in the range of 1×10⁻⁶ Vs/cm to 1×10⁻¹ Vs/cm, more preferably in the range of 5×10⁻⁶ Vs/cm to 1×10⁻² Vs/cm, still more preferably in the range of 1×10⁻⁵ Vs/cm to 1×19⁻² Vs/cm, and most preferably in the range of 5×10⁻⁵ Vs/cm to 1×10⁻² Vs/cm.

The glass transition point of the host material, the transporting layer, and the hole transporting layer contained in the light emitting layer according to the present invention is preferably in the range of 90° C. to 400° C., more preferably in the range of 100° C. to 380° C., still more preferably in the range of 120° C. to 370° C., and most preferably in the range of 140° C. to 360° C.

In the organic electroluminescent device according to the present invention, the maximum wavelength of the emitted blue light is preferably in the range of 390 nm to 495 nm in view of blue color purity and more preferably in the range of 400 nm to 490 nm. The maximum wavelength of the emitted green light is preferably in the range of 500 nm to 590 nm. The light emitting device according to the present invention may have the maximum wavelength of the emitted light greater than or equal to 600 nm and may be a white light emitting device.

In the organic electroluminescent device according to the present invention, the x value of CIE chromaticity of the emitted light is preferably 0.22 or less in view of the blue color purity when the blue light emitting material is used, and more preferably 0.20 or less.

In the organic electroluminescent device according to the present invention, the y value of CIE chromaticity of the emitted light is preferably in the range of 0.25 or less, more preferably 0.20 or less, and most preferably 0.15 or less, in view of the blue color purity.

In the organic electroluminescent device according to the present invention, the half width of an emission spectrum is preferably 100 nm or less, more preferably is 90 nm or less, still more preferably 80 nm or less, and most preferably 70 nm or less, in view of the blue color purity.

The T₁ level (energy level of the least triplet excited state) of the host material contained in the light emitting layer is preferably in the range of 60 Kcal/mol (251.4 KJ/mol) to 90 Kcal/mol (377.1 KJ/mol), more preferably in the range of 62 Kcal/mol (259.78 Ka/mol) to 85 Kcal/mol (356.15 KJ/mol), and most preferably in the range of 65 Kcal/mol (272.35 KJ/mol) to 80 Kcal/mol (335.2 KJ/mol).

The T₁ level (energy level of the least triplet excited state) of the layer (such as the hole transporting layer, the electron transporting layer, the charge blocking layer, and the exciter blocking layer) adjacent to the light emitting layer is preferably in the range of 60 Kcal/mol (251.4 KJ/mol) to 90 Kcal/mol (377.1 KJ/mol), more preferably in the range of 62 Kcal/mol (259.78 KJ/mol) to 85 Kcal/mol (356.15 KJ/mol), and most preferably in the range of 65 Kcal/mol (272.35 KJ/mol) to 80 Kcal/mol (335.2 KJ/mol).

The system, the driving method, and the utilization type of the organic electroluminescent device according to the present invention are not particularly limited. A typical example of the electroluminescent device is an organic EL device.

In the organic electroluminescent device according to the present invention, the light extraction efficiency can be improved by a variety of known techniques. For example, by processing the surface shape of a substrate (for example, forming a micro uneven pattern), or controlling the refractive indexes of the substrate, the ITO layer, and the organic layer, or controlling the thickness of the substrate, the ITO layer, and the organic layer, the light extraction efficiency can be improved, thereby enhancing the external quantum efficiency.

The organic electroluminescent device according to the present invention may be of a so-called top emission type which extracts the light from the positive electrode (see Japanese Unexamined Patent Application Publication Nos. 2003-208109, 2003-248441, 2003-257651, and 2003-282261).

The material of the substrate used in the organic electroluminescent device according to the present invention is not particularly limited, and examples thereof can include an inorganic material such as zirconia-stabilized yttrium and glass, poly ester such as poly ethyleneterephthalate, poly butylene terephthalate, and poly ethylene naphthalate, a high-molecular material such as poly ethylene, poly carbonate, poly ethersulfone, poly arylate, aryldiglycolcarbonate, poly imide, poly cycloolefin, norbornene resin, poly (chlorotrifluoro ethylene), Teflon (registered trademark), and poly tetrafluoro ethylene-poly ethylene copolymer.

The organic electroluminescent device according to the present invention may contain a blue fluorescent compound. Alternatively, a multi-color light emitting device and a full color light emitting device may be manufactured by using a blue light emitting device containing a blue fluorescent compound and the light emitting device according to the present invention together.

The light emitting layer may have a multi-layered structure. The number of stacked layers is preferably in the range of 2 to 50 layers, more preferably in the range of 4 to 30 layers, and most preferably in the range of 6 to 20 layers.

The thicknesses of the layers constituting the stacked structure are not particularly limited, but are preferably in the range of 0.2 nm to 20 nm, more preferably in the range of 0.4 nm to 15 nm, still more preferably in the range of 0.5 nm to 10 nm, and most preferably in the range of 1 nm to 5 nm.

The light emitting layer of the organic electroluminescent device according to the present invention may have a plural-domain structure. For example, the light emitting layer may include different domains. For example, the light emitting layer may include a domain with a volume of about 1 nm³ having a mixture of a host material A and a fluorescent material B and a domain with a volume of about 1 nm³ having a mixture of another host material C and another fluorescent material D. The diameter of each domain is preferably in the range of 0.2 nm to 10 nm, more preferably in the range of 0.3 nm to 5 nm, still more preferably in the range of 0.5 nm to 3 nm, and most preferably in the range of 0.7 nm to 2 nm.

The method of forming the organic layer containing the organic compound complex according to the present invention is not particularly limited, and examples thereof can include a resistance heating deposition method, an electron beam method, a sputtering method, a molecule deposition method, a coating method (such as a spray coating method, a dip coating method, an impregnation method, a roll coating method, a gravure coating method, a reverse coating method, a roll brush method, an air knife coating method, a curtain coating method, a spin coating method, a flow coating method, a bar coating method, a micro gravure coating method, an air doctor coating method, a blade coating method, a squeeze coating method, a transfer roll coating method, a kiss coating method, a cast coating method, an extrusion coating method, a wire-bar coating method, and a screen coating method), an inkjet method, a printing method, and a transfer method. Among them, the resistance heating deposition method, the coating method, and the transfer method are more preferable in view of characteristics and manufacturing thereof.

The positive electrodes serves to supply holes to the hole injecting layer, the hole transporting layer, and the light emitting layer, and may be made of metal, alloy, metal oxide, electrical conductive compound, or mixtures thereof. Among them, the material having a work function of 4 eV or more is preferable. Specific examples of the material can include conductive metal oxide such as tin oxide, zinc oxide, indium oxide, and indium-tin oxide (ITO), metal such as gold, silver, chromium, and nickel, a mixture or stacked material of the metal and the conductive metal oxide, an inorganic conductive material such as copper iodide and copper sulfide, an organic conductive material such as poly aniline, poly thiophene, and poly pyrrole, and a stacked material of the materials and ITO. The conductive metal oxide is preferable and ITO is more preferable in view of productivity, high conductivity, and transparency. The thickness of the positive electrode can be properly selected depending upon the materials, but is preferably in the range of 10 nm to 5 μm, more preferably in the range of 50 nm to 1 μm, and most preferably in the range of 100 nm to 500 nm.

The positive electrode is generally used in the state that it is formed on a soda lime glass substrate, an alkali-free glass substrate, a transparent resin substrate, or the like. When a glass substrate is used, the material thereof is preferably the alkali-free glass so as to reduce the ions eluted from the glass. When the soda lime glass substrate is used, it is preferable that a barrier coating process with silica is performed thereto. The thickness of the substrate is not particularly limited so long as it is enough to maintain the mechanical strength thereof, but when the glass substrate is used, the thickness of the substrate is preferably 0.2 mm or more and more preferably 0.7 mm or more.

A variety of methods can be used to manufacture the positive electrode. For example, when the positive electrode is made of ITO, the positive electrode is formed as a film by the use of an electron beam method, a sputtering method, a resistance heating deposition method, a chemical reaction method )a sol-gel method), or a method of coating a material in which indium-tin oxide is dispersed.

By performing a cleaning process or other processes to the positive electrode# the driving voltage of the device can be decreased or the light emission efficiency thereof can be increased. For example, when the positive electrode is made of ITO, UV-ozone processing or plasma processing is advantageous.

The negative electrode serves to supply electrons to the electron injecting layer, the electron transporting layer, and the light emitting layer, and the material of the negative electrode is selected in consideration of the adhesion to a layer contacting the negative electrode, such as the electron injecting layer, the electron transporting layer, and the light emitting layer, the ionization potential, and the stability. Examples of the material of the negative electrode can include metal, alloy, metal halide, metal oxide, conductive compounds, and mixtures thereof. The specific examples of the material can include alkali metal (such as Li, Na, and K) and fluoride or oxide thereof, alkali earth metal (such as Mg and Ca) and fluoride or oxide thereof, gold, silver, plumbum, aluminum, sodium-potassium alloy or mixture, lithium-aluminum alloy or mixture, magnesium-silver alloy or mixture, and rare earth metal such as indium and yttrium. Among them, the materials having a work function of 4 eV or less are preferable, and aluminum, lithium-aluminum alloy or mixture, and magnesium-silver alloy or mixture are more preferable. The negative electrode may have a single-layered structure of the compound and the mixture described above, or may have a multi-layered structure including the compounds and the mixtures described above. A multi-layered structure such as aluminum/lithium fluoride and aluminum/lithium oxide is preferable. The thickness of the negative electrode can be properly selected depending upon the materials, but is preferably in the range of 10 nm to 5 μm, more preferably in the range of 50 nm to 1 μm, and most preferably in the range of 100 nm to 1 μm.

The electron beam method, the sputtering method, the resistance heating deposition method, the coating method, the transfer method, or the like can be used to manufacture the negative electrode. Two or more metals can be simultaneously deposited as simplexes. In addition, an alloy electrode may be formed by simultaneously depositing a plurality of metals and an alloy adjusted in advance may be deposited.

The sheet resistances of the positive electrode and the negative electrode are preferably low and more preferably several hundreds or less Ω/□.

The light emitting layer may be made of any material as long as it has a function of injecting holes from the positive electrode, the hole injecting layer, or the hole transporting layer at the time of application of a voltage and injecting electrons from the negative electrode, the electron injecting layer, or the electron transporting layer, a function of moving the injected charge carriers, or a function of providing a place for re-coupling the holes and the electrons to emit light. In addition to the organic metal complexes according to the present invention, examples of the material for the light emitting layer can include a variety of metal complexes such as a rare earth complex or a metal complex of benzooxazole, benzoimidazole, benzothiazole, styrylbenzene, polyphenyl, diphenyl butadiene, tetraphenyl butadiene, naphthalimide, coumarin, perylene, perignon, oxadiazole, aldazine, pyrazine, cyclopentadiene, bisstyrylanthracene, quinacridone, pyrrolopyridine, thiadiazoropyridine, styrylamine, aromatic dimethylidine compound, and 8-quinolinol, polymer compounds such as poly thiophene, poly phenylene, and poly phenylene vinylene, transition metal complexes such as organic silane, iridium trisphenylpyridine complexes, and platinum forpyrine complexes, and derivatives thereof. The thickness of the light emitting layer is not particularly limited, but is preferably in the range of 1 nm to 5 μm, more preferably in the range of 5 nm to 1 μm, and most preferably in the range of 10 nm to 500 nm.

The method of forming the light emitting layer is not particularly limited, but is preferably one of the resistance heating deposition method, the electron beam method, the sputtering method, the molecule deposition method, the coating method, the inject method, the printing method, the LB method, and the transfer method, and more preferably one of the resistance heating deposition method and the coating method.

The light emitting layer may be made of a single compound, or may be made of a plurality of compounds. The light emitting layer may have a single layer or a plurality of layers. In this case, the respective layers may emit light of different colors to emit, for example, white light. The single-layered light emitting layer may emit the white light. When the light emitting layer includes a plurality of layers, the respective layers may be made of a single compound or may be made of a plurality of compounds.

The materials of the hole injecting layer and the hole transporting layer may have any one of a function of injecting holes from the positive electrode, a function of transporting holes, and a function of blocking electrons injected from the negative electrode. Specific examples thereof can include a conductive high-molecular oligomer such as carbazole, triazole, oxazole, oxadiazole, imidazole, poly arylalkane, pyrazoline, pyrazolone, phenylenediamine, arylamine, amino-substibuted chalcone, styrylanthracene, fluorenone, hydrazone, stilbene, silazane, aromatic third-degree amine compound, styryl amine compound, aromatic JIMECHIRI DIN compound, porphyrin compound, poly silane compound, poly(N-vinylcarbazole), aniline copolymer, thiophene oligomer, and poly thiophene, an organic silane, a carbon film, the compounds according to the present invention, and derivatives thereof. The thicknesses of the hole injecting layer and the hole transporting layer are not particularly limited, but are preferably in the range of 1 nm to 5 μm, more preferably in the range of 5 nm to 1 μm, and most preferably in the range of 10 nm to 500 nm. The hole injecting layer and the hole transporting layer may have a single-layered structure including one or two or more kinds of the above-mentioned materials, or may have a multi-layered structure including a plurality of layers with a composition of like or different kinds.

The vacuum deposition method, the LB method, the coating method using the material of the hole injecting layer and the hole transporting layer dissolved or dispersed in a solvent, the inkjet method, the printing method, or the transfer method can be used to form the hole injecting layer and the hole transporting layer. When the coating method is used, the material can be dissolved or dispersed along with a resin component. Examples of the resin component can include poly vinyl chloride, poly carbonate, poly styrene, poly methlymethacrylate, poly butylmethacrylate, poly ester, poly sulfon, poly phenyleneoxide, poly butadiene, poly (N-vinylcarbazole), hydrocarbon resin, ketone resin, phenoxy resin, poly amide, ethyl cellulose, vinyl acetate, ABS resin, poly urethane, melamine resin, unsaturated polyester resin, alkid resin, epoxy resin, and silicon resin.

The materials for the electron injecting layer and the electron transporting layer may have any one of a function of injecting electrons from the negative electrode, a function of transporting electrons, and a function of blocking holes injected from the positive electrode. Specific examples thereof can include a variety of metal complexes such as metal complexes of aromatic tetracarbonic acid anhydride such as triazole, oxazole, oxadiazole, imidazole, fluorenone, anthraquinodimethane, anthrone, diphenyl quinone, thiopyrandioxide, carbodimide, fluorenylidene methane, distyrylpyrazine, naphthalene, and perylene, metal complexes of phthalocyanine and 8-quinolinol, and metal complexes having metal phthalocyanine, benzooxazole, or benzothiazole as a ligand, organic silane, and derivatives thereof. The thickness of the electron injecting layer and the electron transporting layer are not particularly limited, but are preferably in the range of 1 nm to 5 μm, more preferably in the range of 5 nm to 1 μm, and most preferably in the range of 10 nm to 500 nm. The electron injecting layer and the electron transporting layer may have a single-layered structure including one or two or more kinds of the above-mentioned materials, or may have a multi-layered structure including a plurality of layers with a composition of like or different kinds.

The vacuum deposition method, the LB method, the coating method using the material of the electron injecting layer and the electron transporting layer dissolved or dispersed in a solvent, the inkjet method, the printing method, or the transfer method can be used to form the electron injecting layer and the electron transporting layer. When the coating method is used, the material can be dissolved or dispersed along with a resin component. Examples of the resin component can include the materials exemplified for the hole injecting layer and the hole transporting layer.

A material of the protective layer may have a function of preventing a material of promoting device deterioration such as moisture and oxygen from entering the device. Specific examples thereof can include metal such as In, Sn, Pb, Au, Cu, Ag, Al, Ti, and Ni, metal oxide such as MgO, SiO, SiO₂, Al₂O₃, GeO, NiO, CaO, BaO, Fe₂O₃, Y₂O₃, and TiO₂, metal fluoride such as MgF₂, LiF, AlF₃, and CaF₂, nitride such as SiNₓ and SiOₓN_{y}, poly ethylene, poly propylene, poly methylmethacrylate, poly imide, poly urea, poly tetrafluoroethylene, poly chlorotrifluoroehtylene, poly dichlorodifluoroethylene, a copolymer of chlorotrifluoroethylene and dichlorodifluoroethylene, a copolymer obtained by copolymerizing tetrafluoroethylene and monomer mixture including at least one kind of co-monomer, fluorine-containing copolymer having a cyclic structure in a copolymer main chain, a water absorbing material having a water absorption rate of 1% or more, and a moisture-resistant material having a water absorption rate of 0.1% or less.

The method of forming the protective layer is not particularly limited, and examples thereof can include the vacuum deposition method, the sputtering method, the reactive spattering method, an MBE (molecular beam epitaxy) method, a cluster ion beam method, an ion plating method, a plasma polymerization method (high-frequency excited ion plating method), a plasma CVD method, a laser CVD method, a thermal CVD method, a gas source CVD method, the coating method, the printing method, and the transfer method.

The applications of the organic electroluminescent device according to the present invention are not particularly limited, but it may be used very suitably in the fields such as display devices, displays, backlights, electronic photographs, lighting light sources, recording light sources, exposing light sources, reading light sources, signboards, interiors, and optical communications.

### EXAMPLE

Hereinafter, embodiments of the present invention will be described, but the present invention is not limited to the embodiments described below.

### Comparative Example 1

A cleaned ITO substrate was placed into a vapor deposition apparatus and was coated with copper phthalocyanine with a thickness of 5 nm. NPD (N,N′-di-a-naphthyl-N,N′-diphenyl-benzidine) was deposited thereon with a thickness of 40 nm. Iridium complex A and CBP were deposited on the resultant structure at a ratio (mass ratio) of 6:94 with a thickness of 30 nm. (In this specification, mass ratio is equal to weight ratio.) BAlq was deposited thereon with a thickness of 6 nm, and then Alq (tris(8-hydroxyquinoline) aluminum complex) was deposited thereon with a thickness of 20 nm. Thereafter, lithium fluoride was deposited with a thickness of 3 nm, and then aluminum was deposited thereon with a thickness of 60 nm, thereby manufacturing an EL device. As a result of applying a DC steady voltage to the EL device to emit light by the use of Source Measure Unit 2400 made by Toyo Corporation, the green light could be obtained.

### Comparative Example 2

A cleaned ITO substrate was placed into a vapor deposition apparatus and was coated with copper phthalocyanine with a thickness of 5 nm. NPD (N,N′-di-a-naphthyl-N,N′-diphenyl-benzidine) was deposited thereon with a thickness of 40 nm. Platinum complex B and CBP were deposited on the resultant structure at a ratio (mass ratio) of 6:94 with a thickness of 30 nm. Then, BAlq was deposited thereon with a thickness of 6 nm, and then Alq (tris(8-hydroxyquinoline) aluminum complex) was deposited thereon with a thickness of 20 nm. Thereafter, lithium fluoride was deposited with a thickness of 3 nm, and then aluminum was deposited thereon with a thickness of 60 nm, thereby manufacturing an EL device. As a result of applying a DC steady voltage to the EL device to emit light by the use of Source Measure Unit 2400 made by Toyo Corporation, the green light could be obtained.

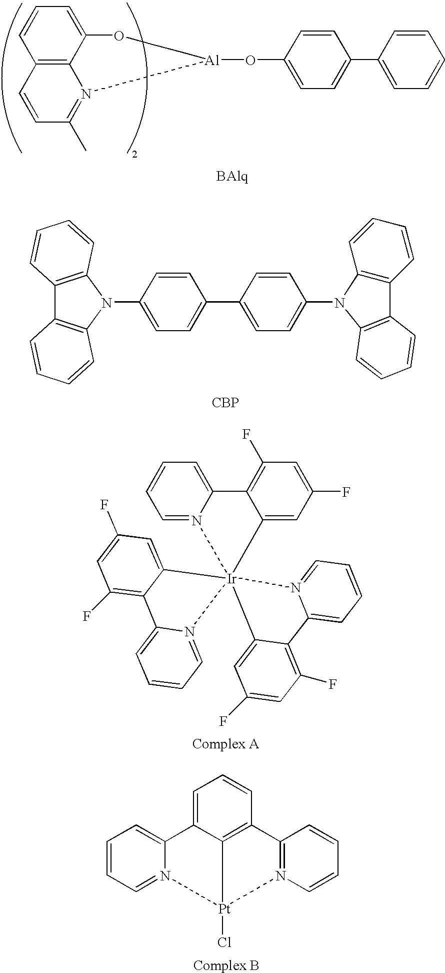

### Example 1

By using Compound (1-1) according to the present invention instead of complex A in the light emitting device according to Comparative Example 1, an EL device was manufactured and estimated similarly to Comparative Example 1. As a result of applying a DC static voltage to the EL device to emit light, blue light was obtained, and the driving durability of the EL device was about two times that of the EL device according to Comparative Example 1.

### Example 2

By using Compound (1-12) according to the present invention instead of complex B in the light emitting device according to Comparative Example 2, an EL device was manufactured and estimated similarly to Comparative Example 1. As a result of applying a DC static voltage to the EL device to emit light, blue-green light was obtained, and the driving durability of the EL device was about two times that of the EL device according to Comparative Example 2.

### Example 3

By using Compound (1-21) according to the present invention instead of CBP in the light emitting device according to Comparative Example 1, an EL device was manufactured and estimated similarly to Comparative Example 1. As a result of applying a DC static voltage to the EL device to emit light, blue-green light was obtained, and the driving durability of the EL device was about two times that of the EL device according to Comparative Example 1.

The same advantages could be obtained from devices employing the other complexes of the present invention.

The organic electroluminescent device according to the present invention can emit light with a short wavelength and excellent durability.

The entire disclosure of each and every foreign patent application from which the benefit of foreign priority has been claimed in the present application is incorporated herein by reference, as if fully set forth.

What is claimed is:

1. An organic electroluminescent device comprising:
a pair of electrodes; and
at least one organic compound layer including a light emitting layer between the pair of electrodes,
wherein the at least one organic compound layer contains an organic metal complex having at least one ligand represented by Formula (1): 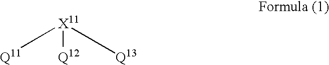
wherein X¹¹ represents an atom or an atom group which is bonded to Q¹¹ to Q¹³; and
Q¹¹ to Q¹³ each independently represents an atom group which is bonded to or coordinates with a metal ion.

2. The organic electroluminescent device according to claim 1,
wherein X¹¹ in the ligand represented by Formula (1) is an atom group containing an atom bonded to Q¹¹ to Q¹³, or a trivalent atom bonded to Q¹¹ to Q¹³.

3. The organic electroluminescent device according to claim 2,
wherein the organic metal complex is an organic metal complex represented by Formula (2) or (3): 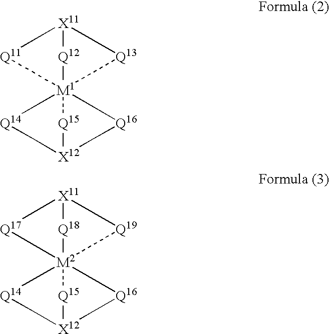
wherein X¹¹ represents an atom group containing an atom bonded to Q¹¹ to Q¹³ or Q¹¹ to Q¹⁹, or a trivalent atom bonded to Q¹¹ to Q¹³ or Q¹⁷ to Q¹⁹;
X¹² represents an atom group containing an atom bonded to Q¹⁴ to Q¹⁶, or a trivalent atom bonded to Q¹⁴ to Q¹⁶;
Q¹¹ to Q¹⁹ each independently represents an atom group which is bonded to or coordinates with a metal ion M¹ or M²;
M¹ represents an iridium ion; and
M² represents a platinum ion.

4. The organic electroluminescent device according to claim 1,
wherein the atom group represented by Q¹¹ to Q¹³ in Formula (1) is an aromatic group or a five-membered or six-membered heterocyclic group containing at least one atom selected from a nitrogen atom, a sulfur atom and an oxygen atom.

5. The organic electroluminescent device according to claim 3,
wherein the atom group represented by Q¹¹ to Q¹⁹ in Formula (2) or (3) is an aromatic group or a five-membered or six-membered heterocyclic group containing at least one atom selected from a nitrogen atom, a sulfur atom and an oxygen atom.

6. The organic electroluminescent device according to claim 1,
wherein the light emitting layer contains a phosphorescent material.

7. The organic electroluminescent device according to claim 1,
wherein when X¹¹ represents an atom group containing an atom bonded to Q¹¹ to Q¹³ in Formula (1), the atom bonded to Q¹¹ to Q¹³ is a carbon atom, a nitrogen atom or a phosphorus atom.

8. The organic electroluminescent device according to claim 3,
wherein when X¹¹ represents an atom group containing an atom bonded to Q¹¹ to Q¹³ or Q¹⁷ to Q¹⁹ in Formula (2) or (3), the atom bonded to Q¹¹ to Q¹³ or Q¹⁷ to Q¹⁹ is a carbon atom, a nitrogen atom or a phosphorus atom.
